(19) United States
(12) Patent Application Publication
(10) Pub. No.: US 2009/0272888 A1
(43) Pub. Date: Nov. 5, 2009

(54) THERMAL INFRARED IMAGING SYSTEM AND ASSOCIATED METHODS FOR RADIOMETRIC CALIBRATION

(76) Inventors: Paul W. Nugent, Bozeman, MT (US); Joseph A. Shaw, Bozeman, MT (US)

Correspondence Address: COOLEY GODWARD KRONISH LLP;ATTN: Patent Group, Suite 1100, 777 - 6th Street, NW, WASHINGTON, DC, 20001, US

(21) Appl. No.: 12/358,658

(22) Filed: Jan. 23, 2009

Related U.S. Application Data
(60) Provisional application No. 61/023,684, filed on Jan. 25, 2008.
(60) Provisional application No. 61/050,133, filed on May 2, 2008.

(51) Int. Cl. G01D 18/00; H01L 25/00

(52) U.S. Cl. 250/252.1; 250/332

(57) ABSTRACT

A thermal infrared (IR) imaging system and associated calibration methods are described. In various illustrative embodiments, techniques are provided for the stabilization and radiometric calibration of a thermal IR imager without stabilization of the device's focal-plane-array (FPA) temperature. In one embodiment, a scene image is corrected for FPA temperature to produce a FPA-temperature-stabilized image, to which radiometric calibration can optionally be added through additional calculations and prior device characterization. In another embodiment, the internal shutter of the thermal IR imager is used as an equivalent external blackbody source to cancel the FPA-temperature-dependent offset from a scene image Radiometric calibration can be included through additional calculations and prior device characterization. In some embodiments, these techniques are combined to correct for dependence on FPA temperature of both the imager's responsivity and its zero-radiance-scene offset.

### PRIORITY

This application claims priority under 35 U.S.C. §119(e) from the following commonly owned and assigned U.S. Provisional Patent Applications: Application No. 61/023,684, Attorney Docket No. MONT-103/00US, entitled “Radiometric Calibration of Thermal Infrared Imagers Using an Internal Shutter as an Equivalent External Blackbody Source,” filed on Jan. 25, 2008; and Application No. 61/050,133, Attorney Docket No. MONT-103/01US, entitled “Radiometric Calibration of Thermal Infrared Imagers Using an Internal Shutter as an Equivalent External Blackbody Source,” filed on May 2, 2008; both of which are incorporated herein by reference in their entirety.

### STATEMENT REGARDING FEDERALLY SPONSORED RESEARCH OR DEVELOPMENT

This invention was made with government support under contracts NNS05AB25H and NMO710820 awarded by the National Aeronautics and Space Administration. The government has certain rights in the invention.

### FIELD OF THE INVENTION

The present invention relates generally to thermal infrared imaging technology. More specifically, but without limitation, the present invention relates to thermal infrared imaging systems and associated methods for radiometrically calibrating such systems.

### BACKGROUND OF THE INVENTION

Thermal infrared (IR) imagers, also known as long wave IR (LWIR) cameras (herinafter a “thermal camera” or simply a “camera”), are used in a tremendously wide range of applications, ranging from environmental monitoring to industrial process control. A growing number of these applications require the camera to be calibrated radiometrically, sometimes in terms of temperature, and other times in terms of radiance [W/(m² sr)] or a similar optical-power-related quantity. In either case, the calibration typically requires quantitatively relating the camera output to source radiance or temperature. This is most commonly done by measuring the camera's output while it views one or more blackbody sources.

From the image(s) of the blackbody source(s), a calibration for the camera can be determined. If the camera's response is sufficiently time invariant, the calibration can be applied to images taken at a later time. The assumption of time-invariant camera response is not true in the case of a microbolometer camera without a thermoelectric cooler (TEC) on the focal plane array (FPA) (hereinafter “a TEC-less microbolometer”). Without the FPA-temperature stabilization that would be provided by the TEC, the response from these cameras depends on the FPA temperature and the scene temperature or radiance. Without stabilization, these cameras cannot obtain radiometrically calibrated data unless the are used together with one or more external calibration sources.

Honeywell was one of the first to produce a TEC-less microbolometer. This camera achieved calibration by performing a per-pixel calibration for every FPA temperature expected to be experienced during operation (Kruse 2002). Irving Sensors Corporation has also developed methods of compensating for the scene temperature errors that would be observed in a TEC-less microbolometer (U.S. Pat. No. 6,476,392). This was done by determining the error in measured temperature that resulted from changing scene and FPA temperatures.

### SUMMARY OF THE INVENTION

Illustrative embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents, and alternative constructions that fall within the spirit and scope of the invention as expressed in the claims.

The present invention can provide a thermal infrared (IR) imaging system and associated calibration methods. One illustrative embodiment is a method for calibrating a thermal IR imager, the method comprising determining correction coefficients in a model for an expected change in response of the thermal IR imager for a given temperature of the focal plane array (FPA) of the thermal IR imager with respect to a response of the thermal IR imager at a predetermined reference temperature of the FPA; acquiring a scene image; measuring the temperature of the FPA; and applying a correction to the scene image based on the correction coefficients and the difference between the measured FPA temperature and the predetermined reference temperature of the FPA to produce a FPA-temperature-stabilized image.

Another illustrative embodiment is a thermal IR imaging system, comprising an image-formation subsystem including a lens and a focal plane array (FPA) configured to receive optical input via the lens; and a stabilization and calibration computing subsystem comprising at least one processor and a memory containing a plurality of program instructions configured to cause the at least one processor to determine correction coefficients in a model for an expected change in response of the image-formation subsystem for a given temperature of the FPA with respect to a response of the image-formation subsystem at a predetermined reference temperature of the FPA, acquire a scene image, measure the temperature of the FPA, and apply a correction to the scene image based on the correction coefficients and the difference between the measured FPA temperature and the predetermined reference temperature of the FPA to produce a FPA-temperature-stabilized image.

Another illustrative embodiment is a method for calibrating a thermal IR imager, the method comprising determining a per-pixel ratio between a blackbody image and a shutter image as a function of shutter temperature, a shutter image being an image of a shutter of the thermal IR imager in a closed position; acquiring a scene image; acquiring a shutter image; measuring the temperature of the shutter; converting the shutter image to an equivalent blackbody image based on the determined per-pixel ratio at the measured shutter temperature; and subtracting the equivalent blackbody image from the scene image to produce an offset-corrected scene image.

Yet another illustrative embodiment is a thermal IR imaging system, comprising an image-formation subsystem including a lens, a focal plane array (FPA) configured to receive optical input via the lens, and a shutter configured to control when the optical input is permitted to reach the FPA; and a stabilization and calibration computing subsystem comprising at least one processor and a memory containing a plurality of program instructions configured to cause the at least one processor to determine a per-pixel ratio between a blackbody image and a shutter image as a function of shutter temperature, a shutter image being an image of the shutter in a closed position; acquire a scene image; acquire a shutter image; measure the temperature of the shutter; convert the shutter image to an equivalent blackbody image based on the determined per-pixel ratio at the measured shutter temperature; and subtract the equivalent blackbody image from the scene image to produce an offset-corrected scene image.

These and other embodiments are described in further detail herein.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings, wherein:

FIG. 1 is an illustration of a portion of a thermal infrared (IR) imager viewing a blackbody source in accordance with the prior art;

FIG. 2 is an illustration relating to use of a converted image of the closed shutter of a thermal IR imager as an equivalent blackbody image in accordance with an illustrative embodiment of the invention;

FIG. 3 is a flow diagram of a method for calibrating a thermal IR imager in accordance with an illustrative embodiment of the invention;

FIG. 4 is a flow diagram of a method for calibrating a thermal IR imager in accordance with another illustrative embodiment of the invention;

FIG. 5 is a flow diagram of a method for calibrating a thermal IR imager in accordance with another illustrative embodiment of the invention;

FIG. 6 is a flow diagram of a method for calibrating a thermal IR imager in accordance with yet another illustrative embodiment of the invention; and

FIG. 7 is a functional block diagram of a thermal IR imaging system in accordance with an illustrative embodiment of the invention.

### DETAILED DESCRIPTION

The invention presented here is a set of techniques that allow for stabilization and subsequent radiometric calibration of TEC-less microbolometer cameras without stabilization of the FPA temperature. The first technique uses only the FPA temperature and the current camera response to produce a stabilized response. In some embodiments of the invention, this is achieved through software rather than through physical stabilization of the camera's FPA temperature. In this FPA-temperature-only technique, the response of the camera to a scene is stabilized to the response the camera would experience at a reference FPA temperature for the scene.

The second technique is a method of using the internal shutter of the camera as an equivalent external blackbody source. This shutter is typically used to perform a flat-field non-uniformity correction every few minutes during normal operation. With proper characterization, an image of this shutter can be converted to an equivalent external blackbody image. This equivalent external blackbody image can then be used in a radiometric calibration in which the camera FPA-temperature-dependent offset is canceled. This offset contains a significant portion of the camera's dependence on FPA temperature.

Various illustrative embodiments of the invention include some or all of the following elements: a) a TEC-less microbolometer camera; b) an internal sensor that measures the temperature of the detector or focal plane array (FPA); c) an internal sensor that measures the temperature at or near the internal shutter, which can be the same sensor as the FPA-temperature sensor; d) a shutter capable of filling the camera field of view; e) laboratory measurements of an external blackbody to derive the coefficients of the FPA-temperature compensation; f) laboratory measurements of the internal shutter to external blackbody conversion; g) laboratory measurements to quantify the camera's gain; h) laboratory measurements to quantify the camera's offset. The shutter and subsequent characterization (component d and g) are not necessary if the shutter-based-external-blackbody technique is not utilized. Measurement of the stabilized camera gain (component g) is not needed if radiometric calibration is not required in a particular application. Measurement of the stabilized camera offset (component h) is not needed if the shutter-based-blackbody technique is used to cancel out the camera's offset.

These two techniques; the FPA-temperature-only stabilization and the shutter-based equivalent blackbody source, can be used to provide stable radiometric calibrations for TEC-less microbolometer cameras. Each of these techniques can be used independently to provide a level of calibration accuracy, or can be used in tandem to provide an improved level of accuracy. The shutter-based correction is of particular importance during times of rapid FPA temperature change, such as just after system power up, where the shutter-based correction can be used to improve the stability of the camera response beyond that of the FPA-temperature-only stabilization alone.

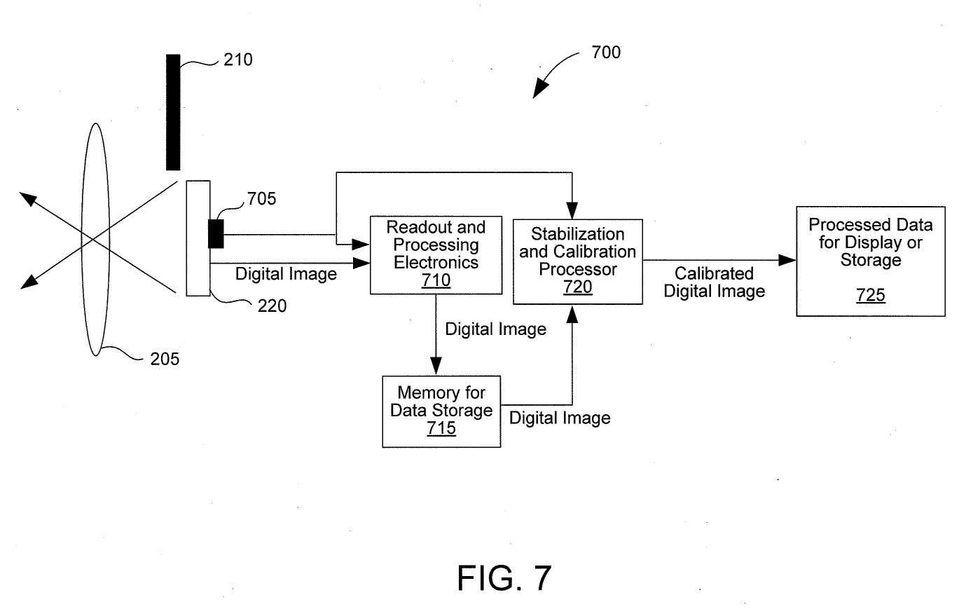

Referring now to the drawings, where like or similar elements are designated with identical reference numerals throughout the several views, and referring in particular to FIG. 7, it is a functional block diagram of a thermal IR imaging system 700 in accordance with an illustrative embodiment of the invention. IR imaging system 700 includes two basic subsystems, an image-formation subsystem and a stabilization and calibration computing subsystem. Some of the elements of these two subsystems are shown in FIG. 7.

The image-formation subsystem includes lens 205, shutter 210, FPA detector 220, and readout and processing electronics 710. Shutter 210 controls when optical input is permitted to reach FPA detector 220. In this illustrative embodiment, the image-formation subsystem also includes FPA-temperature sensor 705. FPA detector 220 outputs digital image data, as indicated in FIG. 7. In other embodiments, an analog detector may be employed instead of a digital detector. In such an embodiment, processing and calibration operations may also be performed using analog circuitry.

The stabilization and calibration computing subsystem includes memory for data storage 715 and stabilization and calibration processor 720. Calibrated output images from the stabilization and calibration computing subsystem may be stored, displayed, or both (725). In this illustrative embodiment, stabilization and calibration processor 720 includes memory for storing a plurality of program instructions that are configured to cause stabilization and calibration processor 720 to carry out the various calibration methods described herein, separately or in combination.

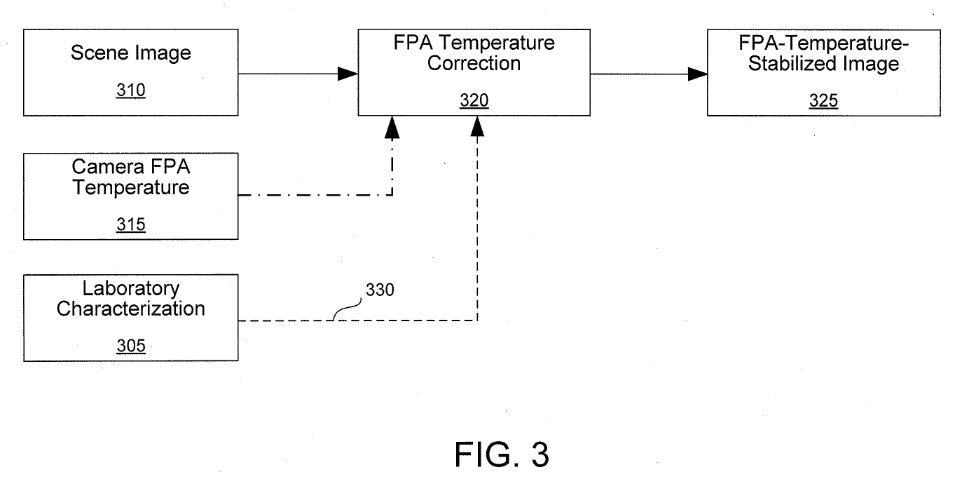

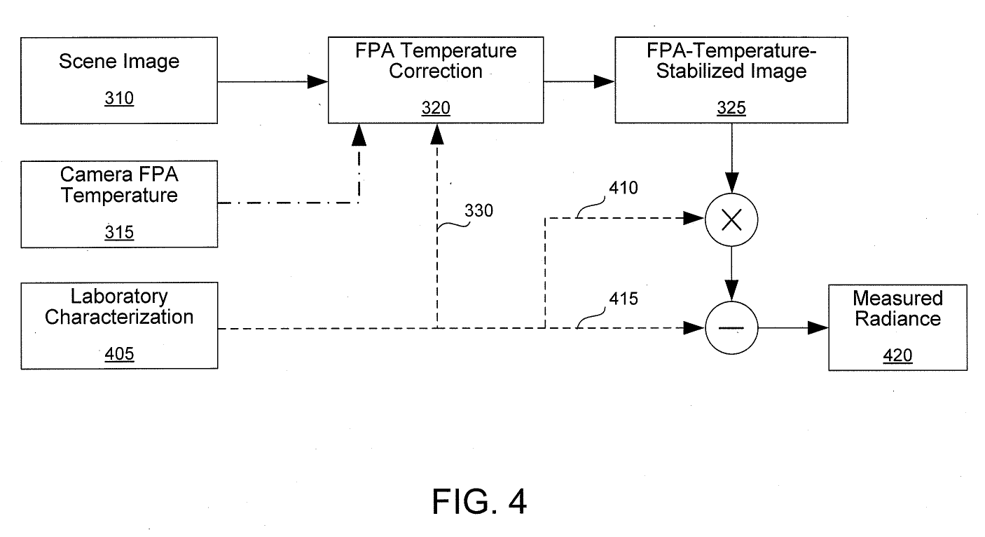

In this embodiment, the scene image (not shown in FIG. 7) and the FPA temperature are measured simultaneously. Using these measurements and previous laboratory characterization, the response of the image-formation subsystem can be stabilized using a FPA-temperature-only technique (see FIGS. 3 and 4).

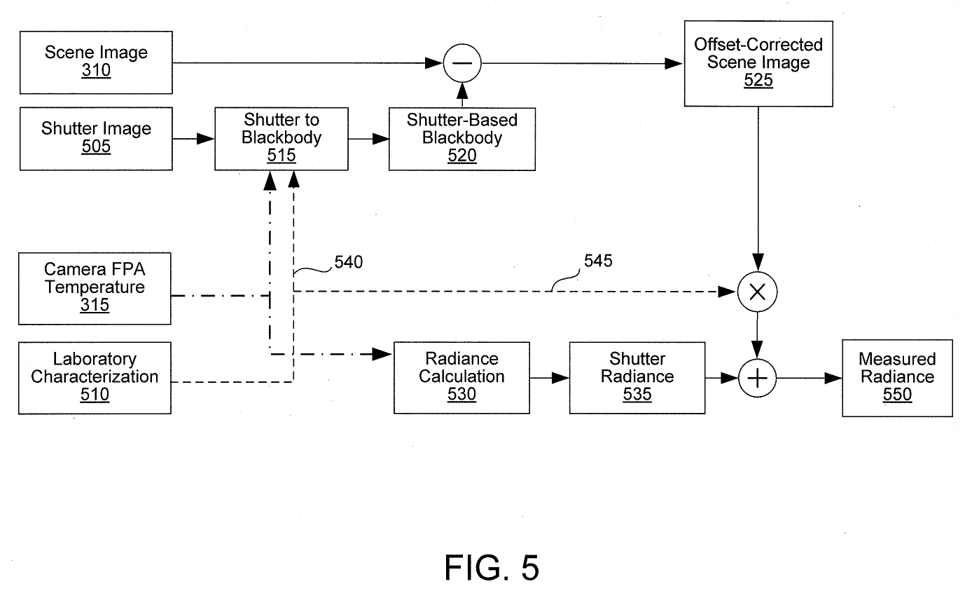

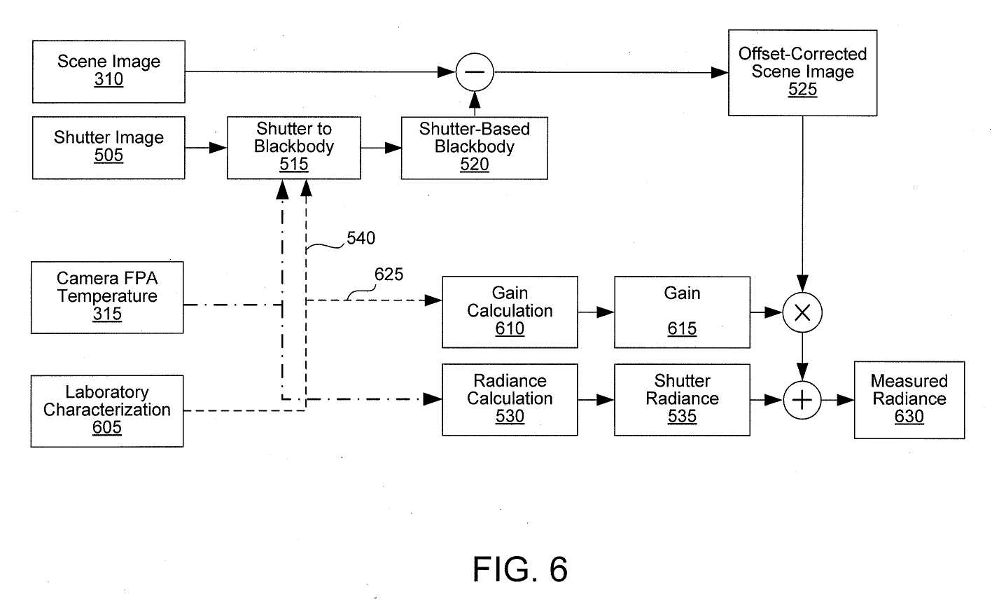

Alternatively, the camera may be directed to close the shutter and capture an image of the shutter, either just before or just after the scene image. Whichever image is captured first is stored in memory for data storage 715. Once both images have been collected, stabilization and calibration processor 720 can apply the shutter-based-blackbody offset correction technique (see FIG. 5) or a combined technique (see FIG. 6).

In some embodiments, the stabilization and calibration computing subsystem is integrated with the image-formation subsystem in a single thermal IR imaging device (e.g., a thermal camera). In other embodiments, the stabilization and calibration computing subsystem resides in a computer that is separate from the image-formation subsystem. In such embodiments, the two separate devices (e.g., camera and computer) are capable of communicating with each other, in some embodiments over a local- or wide-area network.

### Response of TEC-Less Microbolometer-Based LWIR Cameras

The response of a microbolometer-based LWIR camera can be described as a radiance-to-system-output transfer function, similar in form to the following equation:

r=R_{L}L+D. (1)

Here R_{L} is the system responsivity to the scene radiance, which contains values such as electronic gain, direct response to incoming radiance, the extent of the camera's field of view, and the size of the entrance pupil of the camera. The value D is the dark noise or offset within the camera. This is the response to a zero-radiance scene.

In a TEC-less microbolometer the FPA-temperature dependence can be modeled as a temperature-dependent transfer function. Where R_{L} has been replaced with a temperature-dependent responsivity (R_{T}), and the offset D replaced with a temperature-dependent offset (D_{T}). This gives the following equation:

r=R_{T}L+D_{T}, (2)

where r is the response from the camera, R_{T} is the FPA-temperature-dependent responsivity, D_{T} is the FPA-temperature-dependent offset, and L is the scene radiance (a function of scene temperature through the Planck equation and camera bandwidth). The terms R_{T} and D_{T} can be broken down into the following equations.

R_{T}=RₘT+Rₒ (3)

D_{T}=DₘT+Dₒ (4)

In equation 3, Rₘ is the FPA-temperature-dependent portion of the system responsivity, Rₒ is the FPA-temperature-independent portion of the system responsivity, Dₘ is the FPA-temperature-dependent portion of the offset, and Dₒ is the FPA-temperature-independent portion of the offset. Using these equations, the FPA-temperature-dependent transfer function for a TEC-less microbolometer can be written as

r=(RₘT+Rₒ)L+DₘT+Dₒ. (5)

Stabilization using only the FPA Temperature

The technique described in this section is based on using the FPA-temperature-dependent response (r) at a FPA temperature (T) for a scene to calculate a stabilized or corrected response (r_{cor}) that would be experienced at a given reference FPA temperature (T_{ref}) for the same scene. In some embodiments, this stabilization takes place through software rather than through physical stabilization of the camera's FPA temperature. With a software-based stabilization of the camera's response, the usability of these TEC-less cameras is increased and a true radiometric calibration of these cameras can be performed. This correction involves an equation similar to the following:

$${r}_{cor} = \frac{r + b Δ T}{1 - m Δ T} . \qquad ( 6 )$$

In this equation, the corrected response r_{cor} is calculated using the error-containing raw response r, the difference between the current FPA temperature and the reference temperature ΔT, and correction coefficients m and b. Through the use of this equation, the response of the camera can be essentially locked to the response at the reference temperature. This reference temperature, in some embodiments, is selected to lie at the center of the expected operating temperature range of the camera.

### Mathematical Basis for the FPA-Temperature Correction

If the camera views a blackbody radiator that is held at a constant temperature while the camera FPA temperature is changed from the reference temperature T_{ref} to T₂, the response can be represented by the following:

r_{ref}=(RₘT_{ref}+Rₒ)L+DₘT_{ref}+Dₒ and (7)

r₂=(RₘT₂+Rₒ)L+DₘT₂+Dₒ. (8)

In equations 7 and 8, the scene radiance does not change, but the response of the camera is expected to change due to the change in the FPA temperature. To characterize the difference caused by the change in FPA temperature, a difference between these two equations can be taken, giving

r_{ref}−r₂=((RₘT_{ref}+Rₒ)L+DₘT_{ref}+Dₒ)−((RₘT₂+Rₒ)L+DₘT₂+Dₒ) (9)

which can be reduced to

r_{ref}−r₂=LRₘ(T_{ref}−T₂)+Dₘ(T_{ref}−T₂). (10)

At this point the following substitutions will be made to simplify the results:

Δr=r_{ref}−r₂ (11)

ΔT=T_{ref}−T₂, or in a general case (12.a)

ΔT=T_{ref}−T_{FPA}. (12.b)

With these substitutions made, equation 10 can be rewritten as

Δr=LRₘΔT+DₘΔT. (13)

This change in camera response with FPA temperature can be used to represent the response measured at each camera temperature in the following way:

r₂=r_{ref}−Δr and (14)

r_{ref}=r₂+Δr. (15)

The desired correction can be used to convert from one response to the other in a manner similar to the method shown above. Therefore, the difference in camera response at a given temperature can be determined in the following way (see equation 16).

Δr=r_{ref}mΔT+bΔT (16)

In this equation, m and b are coefficients used to calculate the expected change in response for any FPA temperature, given the response r_{ref} at the reference temperature T_{ref} and the difference in FPA temperature from the reference temperature. As mentioned above, the difference in camera response can be represented by equation 13. If equation 16 is a valid representation of the response temperature dependence, then these two equations (13 and 16) should be equivalent. Setting these two equations equal gives

LRₘΔT+DₘΔT=r_{ref}mΔT+bΔT. (17)

Now, expanding the r_{ref} using equation 6 will yield the following

LRₘΔT+DₘΔT=((RₘT_{ref}+Rₒ)L+DₘT_{ref}+Dₒ)mΔT+bΔT. (18)

Distributing the term mΔT results in

LRₘΔT+DₘΔT=(RₘT_{ref}+Rₒ)LmΔT+DₘT_{ref}mΔT+DₒmΔT+bΔT. (19)

There are two parts to equation 19: a portion that contains the scene radiance L and a portion that does not contain the radiance. As these two types of terms show up on both sides of the equation, they must be pair-wise equal. This allows the equation to be broken into two parts (one containing L and one without L):

LRₘΔT=(RₘT_{ref}+Rₒ)LmΔT and (20)

DₘΔT=DₘT_{ref}mΔT+DₒmΔT+bΔT. (21)

We can use these two equations to solve for the coefficient terms m and b. First, dividing equation 20 by L and ΔT gives the following:

Rₘ=(RₘT_{ref}+Rₒ)m. (22)

This equation can now be solved for m, giving

$$m = \frac{{R}_{m}}{( {R}_{m} {T}_{ref} + {R}_{o} )} . \qquad ( 23 )$$

Dividing equation 20 by ΔT gives

Dₘ=DₘT_{ref}m+Dₒm+b, (24)

which can be solved for b to obtain

b=Dₘ−m(DₘT_{ref}+Dₒ) or (25)

$$b = {D}_{m} - \frac{{R}_{m}}{( {R}_{m} {T}_{ref} + {R}_{o} )} ( {D}_{m} {T}_{ref} + {D}_{o} ) . \qquad ( 26 )$$

These equations contain only camera parameters and other known values, such as the reference temperature to which the camera response is stabilized. The value for m as solved for in equation 23 is simply the temperature-dependent portion of the camera's responsivity divided by the camera's responsivity at the reference temperature. However, the value for b expressed by equation 24 is more complicated. This value contains the temperature-dependent portion of the offset Dₘ, from which the offset at the reference temperature scaled by the value m is subtracted.

The method above was derived to allow for the calculation of Δr, the difference or error in a camera response for a temperature difference ΔT, given the known response at the reference temperature r_{ref}. This is not quite what is desired, but these coefficients can be used to calculate a FPA-temperature-corrected response given the measured error-containing response r₂ through the following manipulation. Remember that equation 14 gave the following method of representing the response from the camera, and that equation 16 gave the following method of calculating the error or change in camera response, Δr:

r₂=r_{ref}−Δr and (From equation 14)

Δr=r_{ref}mΔT+bΔT. (From equation 16)

Equation 14 could be re-written as in equation 15, but the coefficients m and b are dependent on the method of correction. These equations can be combined to give the following.

r₂=r_{ref}−r_{ref}mΔT−bΔT or (27)

r₂=r_{ref}(1−mΔT)−bΔT. (28)

From these equations the response r_{ref}; which would be the response at a FPA temperature T_{ref}, can be calculated from the error-containing r₂ at T₂ using the coefficients m and b, and the difference between T₂ and T_{ref}. Using r_{ref} as the FPA-temperature-corrected camera response r_{cor}, the FPA-temperature-corrected camera response can be calculated for any scene using the following equation:

$${r}_{cor} = \frac{{r}_{2} + b Δ T}{1 - m Δ T} . \qquad ( 29 same as equation 6 )$$

This equation locks the camera response to the value the camera would experience at the reference temperature. In some illustrative embodiments, this temperature is selected to lie at the center of the expected operating temperature range of the camera.

This above illustrative embodiment provides a technique that allows for correction of the FPA-temperature-dependent errors in the response of TEC-less microbolometer cameras. This correction is unique from other techniques in that it allows for the correction to take place without requiring a full radiometric calibration of the camera. This correction can take place without knowing specific information about the camera (e.g., spectral characteristics) that would be required in the previous techniques that have been used for camera stabilization. In operation, the response data from the camera can be adjusted for the FPA-temperature-induced errors, thus stabilizing the response of these cameras. Radiometric calibration or other data processing can then be performed on the stabilized camera response.

A method of calculating the value of m and b is presented below in the section entitled “Method of determining the coefficients of the FPA-temperature correction.”

Stabilization using an Internal Shutter as an External Calibration Source

Various illustrative embodiments of the invention include a technique for obtaining a radiometric calibration for a thermal infrared camera without an external blackbody source. In this technique, an internal shutter is used as an equivalent external blackbody source. Various illustrative embodiments include some or all of the following elements: a) an internal shutter; b) an internal sensor that measured the temperature at or near the shutter; c) and internal sensor that measures the temperature at or near the detector array (this could be the same as the shutter-temperature sensor; d) laboratory measurements of an external blackbody to derive the effect of the intervening optics between the shutter and external scene; and e) laboratory measurements to quantify the camera's responsivity and the change in responsivity with temperature. In operation, the camera can be deployed without an external blackbody source but achieves radiometric calibration through the combined use of a temperature-adjusted responsivity and a real-time offset determined by the internal shutter.

Characterization of the shutter with external blackbody differences allows for full removal of the FPA-temperature-dependent offset, leaving only the FPA-temperature-dependent responsivity that requires further temperature compensation to achieve a stable calibration. A description of the method of correcting and deriving the temperature dependence in the responsivity is described in previous sections.

In various illustrative embodiments of the invention, the internal shutter of the camera is used as an equivalent external blackbody source. This shutter is typically used to perform a flat-field non-uniformity correction every few minutes during normal operation. We have shown that, with proper characterization, this shutter can be used as a blackbody source by recording an image of the closed shutter and modifying the shutter image based on measured properties of the camera and the attached lens to produce an equivalent external-blackbody image. This equivalent external blackbody image can be used to perform a radiometric offset correction to the camera that can be measured consecutively with (within a short time before or after) the scene image. This is particularly important for microbolometer detectors operated without a TEC on the FPA. In such TEC-less systems, the signal output form the camera is dependent on both the scene and the temperature of the camera FPA. Using the described shutter-based equivalent-blackbody reference cancels out the temperature dependence of the camera offset calibration, thereby requiring only compensation for the temperature-dependent change in responsivity.

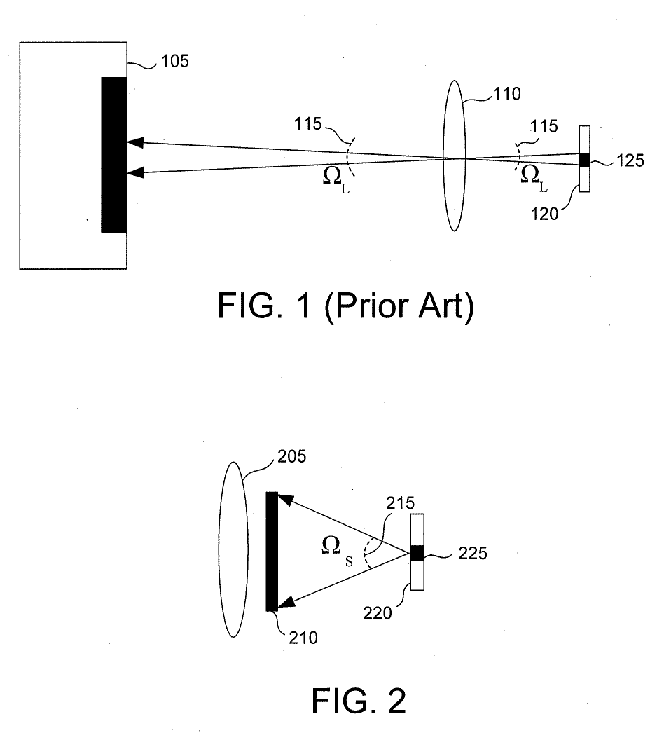

In one illustrative embodiment, the shutter is not directly used to produce a blackbody reference; rather, the image of the shutter is modified to represent an equivalent external blackbody source. This modification to the image is performed because the radiometry is not consistent between viewing a blackbody source outside the camera and viewing the shutter as an internal blackbody source. These different layouts are shown in FIGS. 1 and 2 and are described mathematically in equations 30 and 31, which describe the power detected from an external blackbody scene (FIG. 1) and the power detected from an internal shutter (FIG. 2).

P_{DBB}=L_{BB}A_{L}Ω_{L}τ_{L}τ_{F} [Watts] (external blackbody scene) (30)

P_{DS}=L_{S}A_{P}Ω_{S}τ_{F} [Watts] (internal shutter) (31)

In the prior-art approach of FIG. 1, FPA detector 120 receives optical input via lens 110 from blackbody scene 105. The symbol Ω_{L} indicates the projected solid angle 115 defining the field of view. An image is formed on Pixel 125 of FPA detector 120.

In contrast with FIG. 1, in FIG. 2, in accordance with an illustrative embodiment of the invention, FPA detector 220 receives an image of closed shutter 210 behind lens 205. The symbol Ω_{S} indicates the projected solid angle of view for the detector and shutter system. Pixel 225 is formed on FPA detector 220.

When viewing the blackbody through the lens, the power on a single pixel at the detector, P_{DBB}, is determined as a function of the following: the radiance emitted from the blackbody, L_{BB}, the area of the lens, Ω_{L}, the projected solid angle defining the field of view for the lens detector-pixel system, Ω_{L}, transmission of the lens, τ_{L}, and the transmission of the filter attached to the focal plane array, τ_{F}. This changes when the shutter is closed as the detector no longer views the scene through the lens, but rather it views the shutter directly. In this case the power on the detector, P_{DS}, is determined as a function of the following: the radiance emitted from the shutter, L_{S}, the area of a single detector pixel, A_{P}, the projected solid angle field of view for the detector and shutter system, Ω_{S}, and the transmission of the filter attached to the focal plane array, τ_{F}. The measured per-pixel ratio between the powers detected when viewing an external blackbody, P_{DBB}, and detected when viewing the internal shutter, P_{DS}, can be used to convert an image of the internal shutter to an equivalent external blackbody source.

With this technique, the offset and scene are both measured with the same FPA temperature. Thus, the calculated offset contains both temperature-independent and temperature-dependent components. Therefore, by measuring the shutter and image in rapid succession, the FPA-temperature-dependent portion of the offset cancels out of the calibration equation. The result is that only the responsivity term of the calibration equation requires compensation for changes in FPA temperature.

### Mathematical Basis for the Shutter-to-External-Blackbody Conversion

The conversion of the internal shutter to equivalent external blackbody is based on the assumption that shutter acts as a blackbody at the measured shutter temperature. When both the blackbody and the shutter are at the same temperature, the radiances of both sources, L_{BB} and L_{S}, are equivalent. Solving for the radiance values from equations 30 and 31 gives the following:

external blackbody

$${L}_{BB} = \frac{{P}_{DBB}}{{A}_{L} {Ω}_{L} {τ}_{L} {τ}_{F}} [ W \cdot {m}^{- 2} \cdot {sr}^{- 1} ] , \qquad ( 32 )$$

internal shutter:

$${L}_{BB} = \frac{{P}_{DS}}{{A}_{P} {Ω}_{S} {τ}_{F}} [ W \cdot {m}^{- 2} \cdot {sr}^{- 1} ] . \qquad ( 33 )$$

Setting these radiances equal gives

$$\frac{{P}_{DBB}}{{A}_{L} {Ω}_{L} {τ}_{L} {τ}_{F}} = \frac{{P}_{DS}}{{A}_{P} {Ω}_{S} {τ}_{F}} . \qquad ( 34 )$$

This equation can be rearranged to give P_{DBB}, the power measured when viewing an external blackbody. τ_{F} appears on both sides of the equations and cancels out, leaving:

$${P}_{DBB} = {P}_{DS} [ \frac{{A}_{L} {Ω}_{L} {τ}_{L}}{{A}_{P} {Ω}_{S}} ] [ W ] . \qquad ( 35 )$$

In this equation the only difference between P_{DBB} and P_{DS} is a scaling factor in square brackets. This scale factor depends on properties of the camera which are generally stable in time but vary from pixel to pixel. This equation can be rewritten as the ratio between the powers measured in each case to give:

$$\frac{{P}_{DL}}{{P}_{DS}} = [ \frac{{A}_{L} {Ω}_{L} {τ}_{L}}{{A}_{P} {Ω}_{S}} ] . \qquad ( 36 )$$

This equation shows that the differences between the internal shutter image and the external blackbody images can be measured as a per-pixel ratio of the external-blackbody and the internal-shutter signal. By measuring this ratio over the range of temperatures expected to be experienced by the camera, any temperature dependence can be determined. Once measured, the inverse of this ratio can be applied to shutter images, allowing any image of the shutter to act as an equivalent external blackbody source.

### Mathematical Basis for the Shutter-Based Compensation for FPA Temperature

Above, we stated that consecutively recording images of the shutter and the scene will cancel out the FPA-temperature-dependent offset contained in the data. Demonstration of this with mathematics starts with the linear calibration equation used to calibrate linear-response thermal cameras:

L=gr_{cor}+o_{c} (37)

In this equation 37, L is the measured scene radiance, r_{cor} is the FPA-temperature-corrected response, g is a laboratory-measured calibration gain, and o_{c} is the calibration offset determined from a shutter-based blackbody technique. Before calibration, the raw response from the camera can optionally be corrected to compensate for FPA temperature. This is done by removing errors from the temperature-dependent change in responsivity and temperature-dependent change in offset, through equation 38.

$${r}_{cor} = \frac{r + b Δ T}{1 - m Δ T} \qquad ( 38 same as equation 6 )$$

In this equation 38, r is the raw response from the camera, r_{cor} is the corrected response after the removal of the FPA temperature dependence, ΔT is the difference in temperature from a reference temperature (typically chosen to lie in the center of the expected operating FPA temperature range), m is the correction coefficient for the temperature-dependent responsivity, and b is the correction coefficient for the temperature-dependent offset. The coefficients have been measured in a laboratory setting, usually with a thermal chamber and blackbody. Substituting equation 38 for r_{cor} in the calibration equation, equation 37, gives:

$$L = g ( \frac{r + b Δ T}{1 - m Δ T} ) + {o}_{c} \qquad ( 39 )$$

The offset term, o_{c} is measured using the internal-shutter-to-external-blackbody technique described here. This value is determined by multiplying the laboratory measured calibration gain, g, by an equivalent external blackbody image of the shutter, r_{sbbcor} (which has been corrected for FPA temperature), and subtracting this product from the calculated radiance for a blackbody at the shutter temperature, L_{S} as is shown in equation 40.

o_{c}=L_{S}−gr_{sbbcor} (40)

The correction of the camera response for the FPA temperature takes place after the conversion of the internal shutter to an external-blackbody. Therefore, the shutter-based equivalent blackbody after correction is expressed by equation 41.

$${r}_{sbbcor} = \frac{\frac{{r}_{s}}{{S}_{R} ( {T}_{s} )} + b Δ T}{1 - m Δ T} \qquad ( 41 )$$

In this equation, the shutter image is first converted to an equivalent external blackbody image by scaling the raw per-pixel response rₛ by the inverse of the internal-shutter-to-external-blackbody temperature-dependent ratio S_{R}(Tₛ), where Tₛ is the shutter temperature. The scaled image is then corrected for FPA temperature. Substituting equation 41 into equation 40 gives a full equation for the offset calculation.

$${o}_{c} = {L}_{S} - g ( \frac{\frac{{r}_{s}}{{S}_{R} ( {T}_{s} )} + b Δ T}{1 - m Δ T} ) \qquad ( 42 )$$

Replacing the offset, o_{c}, in equation 39 with equation 42 gives:

$$L = g ( \frac{r + b Δ T}{1 - m Δ T} ) + {L}_{S} - g ( \frac{\frac{{r}_{s}}{{S}_{R} ( {T}_{s} )} + b Δ T}{1 - m Δ T} ) . \qquad ( 43 )$$

This can be rearranged to consolidate variables giving:

$$L = g [ r - \frac{{r}_{s}}{{S}_{R} ( {T}_{s} )} ] ( \frac{1}{1 - m Δ T} ) [ 1 + b Δ T - b Δ T ] + {L}_{S} . \qquad ( 44 )$$

The temperature dependence in the camera offset, bΔT, appears twice, but with opposite signs. Thus this portion of the FPA temperature dependence simply cancels out, giving a final calibration equation:

$$L = {L}_{S} + g ( \frac{1}{1 - m Δ T} ) [ r - \frac{{r}_{s}}{{S}_{R} ( {T}_{s} )} ] . \qquad ( 45 )$$

Thus, we see that the use of a shutter image as a blackbody reference, taken at the same FPA temperature that is in effect for the scene image, causes the temperature-dependent offset to cancel out, leaving only the temperature dependence of the responsivity. Experimentation has shown that the temperature-dependence is smaller for the responsivity than for the offset.

The above technique simplifies the FPA-temperature compensation in TEC-less microbolometer cameras and allows the internal shutter of any thermal-imaging camera to act as an equivalent external blackbody source.

A method of calculating the value S_{R}(Tₛ) is presented below.

Stabilization of the Camera Response using only the FPA Temperature

Refer to FIG. 3. In this illustrative embodiment, the camera response is stabilized for changes in FPA temperature. However, in this particular embodiment, a radiometric calibration of the data is not performed. The scene image 310 and the FPA temperature 315 are measured consecutively. Then, using the calculated values for the coefficients 330 of the temperature dependence of the responsivity and offset, m and b, respectively, based on laboratory characterization 305, the camera response is stabilized to the response the camera would have at T_{ref} using equation 6 (Block 320). The result is a FPA-temperature-stabilized image 325.

Stabilization and Radiometric Calibration using only the FPA Temperature

Refer to FIG. 4. In this illustrative embodiment, the camera response is first stabilized for changes in FPA temperature, then a radiometric calibration of the data is performed. The scene image 310 and the FPA temperature 315 are measured consecutively. Then, using the calculated values for the coefficients 330 of the temperature dependence of the responsivity and offset, m and b, respectively, based on laboratory characterization 405, the camera response is stabilized to the response the camera would have at T_{ref} using equation 6 (Block 320). To the stabilized response (FPA-temperature-stabilized image 325), a camera calibration gain 410 and an offset 415 (also based on laboratory characterization 405) are applied using parameters that have been measured at the reference temperature T_{ref}. The radiometric calibration is determined without using a shutter image as an equivalent blackbody source, but with decreased accuracy. The result is a radiometrically-calibrated measured radiance 420 of the scene to which scene image 310 corresponds.

Stabilization and Radiometric Calibration using only the Shutter-Based Blackbody

Refer to FIG. 5. In this illustrative embodiment, the camera is radiometrically calibrated using the shutter as an equivalent external blackbody source. Consecutively (or sufficiently close in time) with the scene image 310, an image of the internal shutter (505) is collected. Consecutively with the shutter image 505, the temperature of the shutter is measured. In one illustrative embodiment, the FPA temperature (Camera FPA temperature 315) is used as the shutter temperature. Using this temperature and S_{R}(Tₛ) 540, which is obtained from laboratory characterization 510, the shutter image 505 is converted to an equivalent external blackbody image 520 (computed at Block 515). This image is subtracted from the scene image 310 to produce an offset-corrected scene image 525, the camera offset including any FPA-temperature dependence being canceled by this difference.

This image (525) is multiplied by the camera calibration gain 545 (measured at an FPA temperature within the operating range of the camera; in one embodiment, this FPA temperature is at the center of the operating range). The resulting image is then added to a calculated radiance (535) for a blackbody at the measured shutter (or FPA) temperature (this blackbody radiance is calculated at Block 530). This process provides a radiometric calibration (measured radiance 550) without using the FPA-temperature correction (see FIGS. 3 and 4), but with decreased accuracy.

Stabilization and Radiometric Calibration using a Combined Technique

Refer to FIG. 6. In this illustrative embodiment, the FPA-temperature correction and the shutter-based external blackbody techniques are combined to produce a radiometrically calibrated image. Consecutively (or sufficiently close in time) with the scene image 310, an image of the internal shutter (505) is collected. Consecutively with the shutter image 505, the temperature of the shutter is measured (Block 315). In one illustrative embodiment, the FPA temperature is used as the shutter temperature. Using this temperature and the S_{R}(Tₛ) 540, obtained from laboratory characterization 605, the shutter image 505 is converted to an equivalent external blackbody image 520 (computed at Block 515). This image (520) is subtracted from the scene image 310 to produce an offset-corrected scene image 525, the camera offset including any FPA-temperature dependence being canceled by this difference.

Then, using the calculated values for the coefficient for the temperature dependence of the responsivity (m) and the calibration gain measured at T_{ref} (625), a calibration gain 615 is calculated (Block 610) for the current FPA temperature and multiplied by the offset-corrected scene image 525. This value is then added to the calculated radiance 535 for a blackbody at the shutter temperature (calculated at Block 530). This process provides the most accurate radiometric calibration (measured radiance 630), but requires both the shutter and FPA-temperature correction and therefore requires the most characterization of the camera of any of the methods describe here.

In FIG. 6, the shutter-based external blackbody technique is employed first, followed by FPA temperature correction. In an alternative embodiment, FPA temperature correction is applied first, followed by the shutter-based external blackbody technique. In such an embodiment, the camera data is first corrected for FPA temperature through application of equation 6 (see FIG. 3). Next, a shutter image is converted to an equivalent blackbody image, as described above, and that equivalent blackbody image is corrected for FPA temperature (see equation 41 and associated discussion). The FPA-temperature-corrected equivalent blackbody image is then subtracted from the FPA-temperature-stabilized image. The difference is then multiplied by the camera gain measured at T_{ref} to obtain the difference in radiance between the scene and the equivalent blackbody image. By adding to this scaled difference image the calculated radiance of a blackbody at the measured shutter temperature (see shutter radiance 535 in FIGS. 5 and 6), a radiometrically-calibrated measured radiance of the scene is obtained as in the embodiment of FIG. 6.

### Method of Determining the Coefficients of the FPA-Temperature Correction

The FPA-temperature correction coefficients m and b can be calculated through the following method. First, a series of measurements are taken with the camera viewing a blackbody source while the temperature of the camera is changed. If a constant-temperature blackbody is viewed with the camera at a minimum of three different temperatures, a correction can be built. One FPA temperature is selected as a reference temperature; for example, use T₁ as the reference FPA temperature. The following three responses are obtained from the camera:

r₁=(RₘT₁+Rₒ)L+DₘT₁+Dₒ, (46)

r₂=(RₘT₂+Rₒ)L+DₘT₂+Dₒ, and (47)

r₃=(RₘT₃+Rₒ)L+DₘT₃+Dₒ. (48)

Using T₁ as the reference temperature the following differences can be determined

Δr₁₂=r₁−r₂, (49)

Δr₁₃=r₁−r₃, (50)

ΔT₁₂=T₁−T₂, and (51)

ΔT₁₃=T₁−T₃. (52)

To solve for m and b the following matrix can be created.

$$[ \begin{matrix}Δ {r}_{12} \\ Δ {r}_{13}\end{matrix} ] = [ \begin{matrix}{r}_{1} Δ {T}_{12} & Δ {T}_{12} \\ {r}_{1} Δ {T}_{13} & Δ {T}_{13}\end{matrix} ] ⋆ [ \begin{matrix}m \\ b\end{matrix} ] \qquad ( 53 )$$

Inverting this matrix and solving for m and b gives:

$$[ \begin{matrix}m \\ b\end{matrix} ] = {[ \begin{matrix}{r}_{1} Δ {T}_{12} & Δ {T}_{12} \\ {r}_{1} Δ {T}_{13} & Δ {T}_{13}\end{matrix} ]}^{- 1} ⋆ [ \begin{matrix}Δ {r}_{12} \\ Δ {r}_{13}\end{matrix} ] \qquad ( 54 )$$

It is important to note that in this correction the absolute temperature or radiance of the blackbody target is not needed. The blackbody target is only required to remain stable during the temperature measurements. The correction is performed using only the responses and the FPA temperature of the camera. Therefore, no additional information about the camera's spectral response, the temperature of the blackbody, or imperfections in the blackbody is needed. This is true as long as these values remain constant, which is a valid assumption in most laboratory situations. Performing this technique at two blackbody temperatures improves the accuracy of the coefficients in the correction. In this case you would have two reference responses, one for each blackbody temperature. This would cause the matrix to be over determined, and a pseudo matrix inversion would be required.

### Method of Determining the Coefficients of the Shutter-to-Blackbody Conversion

The function for the shutter temperature dependent ratio S_{R}(Tₛ) used to convert an internal shutter image to an equivalent external blackbody can be calculated through the following method. First, a series of measurements are taken with the camera viewing a blackbody in a thermal chamber. The thermal chamber is held at a constant temperature while the FPA temperature stabilizes. While the camera FPA temperature stabilizes, the controlled blackbody is continually being set to be equal to the camera temperature. Once the camera temperature is stable and the blackbody has been at the same temperature as the camera for a sufficient length of time, a series of images is taken, alternating between images of the shutter and images of the blackbody. The flat-field function of the camera should be used during this data collection if a flat-field correction is to be used during deployment.

Once a sufficiently-sized data set has been collected at the current FPA temperature, the thermal chamber temperature is increased. The process is then repeated again, allowing the camera to stabilize and the blackbody to match the camera temperature.

In post processing, the ratio between the blackbody image and the shutter image is calculated through an equation such as the following:

$${S}_{R} = \frac{{P}_{DL}}{{P}_{DS}} = [ \frac{{A}_{L} {Ω}_{L} {T}_{L}}{{A}_{P} {Ω}_{S}} ] . \qquad ( 55 )$$

In this equation, S_{R} is the per-pixel shutter ratio of the blackbody image (P_{DL}) to the shutter image (P_{DS}). If this is repeated for multiple camera temperatures, one obtains a series of ratios for each pixel such as the following:

$$\begin{matrix}{S}_{R 1} = \frac{{P}_{DL 1}}{{P}_{DS 1}} at {T}_{s} = {T}_{1} , & ( 56 ) \\ {S}_{R 2} = \frac{{P}_{DL 2}}{{P}_{DS 2}} at {T}_{s} = {T}_{2} , & ( 57 ) \\ {S}_{R 3} = \frac{{P}_{DL 3}}{{P}_{DS 3}} at {T}_{s} = {T}_{3} , and so on . & ( 58 )\end{matrix}$$

After collecting data at a sufficient number of data points, a function S_{R}(Tₛ) can be fit for each pixel between the calculated ratio S_{R} and the shutter temperature Tₛ, allowing the shutter ratio to be calculated given any shutter temperature Tₛ. It has been found that a first-order linear fit was sufficient to characterize S_{R}(Tₛ) for at least one specific type of camera.

### Experimental Results

In one particular experiment, a TEC-less microbolometer camera was placed inside an environmental chamber while viewing a blackbody that filled the entire field of view for the camera. The data were collected as the chamber air temperature varied based on data from a weather station to simulate the camera being outside on a summer day in Bozeman, Mont. As the chamber air temperature varied, the blackbody temperature was also varied but on a much slower time scale. When the blackbody temperature was changed, it was set to a multiple of 10° C. between 10° C. and 50° C. and then held constant at the new temperature for a variable length of time, no shorter than 70 minutes and no longer than 320 minutes.

During this experiment, the internal temperature of the FPA and shutter images was collected consecutively with the blackbody images. In post processing, the combined technique was used in which the temperature-dependent responsivity and offset correction for stabilizing the data is used in conjunction with the shutter-based-external-blackbody correction for radiometric calibration. For much of the 24-hour period for which data was analyzed, the difference between the camera's reported temperature and the blackbody temperature fell within the bounds of the blackbody uncertainty.

### Summary and Additional Applications

In many thermal infrared imaging applications, use of the above techniques can eliminate the costly and space-intensive blackbody source, provide radiometric calibration of otherwise uncalibrated TEC-less cameras, and improve the stability and accuracy of data from thermal imaging cameras. Specific market areas in which this technique may be applied include, without limitation, the following: measuring atmospheric and cloud radiation for environmental and climate studies; measuring atmospheric radiation for characterizing free-space optical communication paths; and ground-, air-, and satellite-based remote-sensing sensors for military, defense, or homeland-security applications, etc.

The above techniques benefit, for example, any application in which a thermal camera is required and wherein the cost, space, or weight of an external blackbody is not desired or practical. Because these techniques remove the need for an external blackbody source, it reduces cost, reduces space, and reduces weight of the thermal infrared imaging system. If carefully implemented, some embodiments can produce a radiometric uncertainty on the order of 0.3 W/(m² sr) or approximately 0.4° C. for a 25° C. scene (viewed by a camera that integrates across the long-wave infrared band of approximately 8-14 μm wavelength). This is better than the calibration uncertainty of 1-2° C. that is typically available for thermal cameras used with laboratory calibration without an external blackbody source.

The application of these techniques is not limited to TEC-less microbolometer cameras. This type of correction could be applied to non-microbolometer based thermal cameras, some of which are TEC-less and operate without other forms of temperature stabilization. These corrections could be applied to TEC-stabilized microbolometer based thermal cameras. Even with a TEC element, the FPA temperature can vary, causing a similar error as observed in a TEC-less camera, though smaller in magnitude. The invention described here could be used to improve the stability of the camera response beyond the stability obtainable from a TEC alone. There are also applications beyond thermal imaging in stabilization and calibration of other temperature-sensitive sensors.

In conclusion, the present invention provides, among other things, a thermal IR imaging system and associated methods for calibrating such a system. Those skilled in the art can readily recognize that numerous variations and substitutions may be made in the invention, its use, and its configuration to achieve substantially the same results as achieved by the embodiments described herein. Accordingly, there is no intention to limit the invention to the disclosed exemplary forms. Many variations, modifications, and alternative constructions fall within the scope and spirit of the disclosed invention as expressed in the claims.

### LIST OF TERMS AND SYMBOLS

A_{L} Area of the lens or entrance pupil
A_{P} Area of a pixel in the detector array
b Correction coefficient for the FPA-temperature-dependent offset
D System offset or dark noise, the response to a zero-radiance scene
Dₘ The temperature-dependent portion of D_{T}
Dₒ The temperature-independent portion of D_{T}
D_{T} System offset for a TEC-less FPA, this contains both temperature-dependent and a temperature-independent portions
FPA Focal plane array
g Calibration gain for a camera
IR Infrared
L Radiance of the scene
L_{BB} Radiance from a blackbody
L_{S} Radiance of the shutter
LWIR Long Wave Infrared
m Correction coefficient for the FPA-temperature-dependent responsivity
o_{c} Calibration offset for a camera
P_{DBB} Power detected while viewing a blackbody
P_{DS} Power detected while viewing the shutter
r system response to a scene, unique for each pixel
r_{cor} system response corrected for FPA temperature
r_{ref} system response to a particular scene at the reference temperature T_{ref}
rₛ System response while viewing the shutter
r_{sbbcor} System response while viewing the shutter corrected to look like an equivalent external blackbody and corrected for FPA temperature
Δr Difference between the current response to a scene and r_{ref} for the same scene
R_{L} System responsivity to scene radiance, sometimes refereed to as “gain”
Rₘ The temperature-dependent portion of R_{T}
Rₒ The temperature-independent portion of R_{T}
R_{T} System responsivity for a TEC-less FPA, containing both temperature-dependent and temperature-independent portions
S_{R}(Tₛ) The internal shutter to external blackbody conversion function
T The temperature of the FPA
TEC Thermoelectric cooler
TEC-less Without a thermoelectric cooler
T_{FPA} The temperature of the FPA
T_{ref} Reference temperature to which the FPA-temperature dependence is referenced
ΔT Difference between current FPA temperature and Tref
τ_{F} Transmittance of the filter and detector combination
τ_{L} Transmittance of the lens
Ω_{L} Projected solid-angle field of view for the camera while looking through the lens
Ω_{S} Projected solid-angle field of view for the camera while viewing the shutter

What is claimed is:

1. A method for calibrating a thermal infrared (IR) imager, the method comprising:
determining correction coefficients in a model for an expected change in response of the thermal IR imager for a given temperature of a focal plane array (FPA) of the thermal IR imager with respect to a response of the thermal IR imager at a predetermined reference temperature of the FPA;
acquiring a scene image;
measuring the temperature of the FPA; and
applying a correction to the scene image based on the correction coefficients and the difference between the measured FPA temperature and the predetermined reference temperature of the FPA to produce a FPA-temperature-stabilized image.

2. The method of claim 1, wherein the determining includes:
measuring a response of the thermal IR imager to a constant-temperature blackbody source for each of a plurality of FPA temperatures;
selecting a particular one of the plurality of FPA temperatures;
computing a change in response of the thermal IR imager for each of the other FPA temperatures in the plurality of FPA temperatures with respect to the response of the thermal IR imager at the particular one of the plurality of FPA temperatures;
constructing a system of equations in which each computed change in response depends linearly on the difference between the FPA temperature at which the changed response was measured and the particular one of the plurality of FPA temperatures, the equations in the system of equations including first and second correction coefficients; and
solving the system of equations for the first and second correction coefficients.

3. The method of claim 1, further comprising:
measuring, prior to the acquiring, a gain and a zero-radiance-scene offset of the thermal IR imager at the predetermined reference temperature of the FPA; and
multiplying the FPA-temperature-stabilized image by the gain and subtracting the zero-radiance-scene offset to produce a radiometrically-calibrated measured radiance of the scene corresponding to the scene image.

4. The method of claim 1, wherein the thermal IR imager is a microbolometer camera lacking a thermoelectric cooler to stabilize the temperature of the FPA.

5. The method of claim 1, wherein the thermal IR imager is a microbolometer camera that includes a thermoelectric cooler to stabilize the temperature of the FPA.

6. The method of claim 1, wherein the predetermined reference temperature of the FPA lies at the center of a predetermined FPA-temperature operating range of the thermal IR imager.

7. The method of claim 1, further comprising:
determining, prior to acquiring the scene image, a per-pixel ratio between a blackbody image and a shutter image as a function of shutter temperature, a shutter image being an image of a shutter of the thermal IR imager in a closed position;
acquiring a shutter image;
measuring the temperature of the shutter;
converting the shutter image to an equivalent blackbody image based on the determined per-pixel ratio at the measured shutter temperature;
correcting the equivalent blackbody image for FPA temperature based on the correction coefficients and the determined per-pixel ratio at the measured shutter temperature to produce a FPA-temperature-corrected equivalent blackbody image;
subtracting the FPA-temperature-corrected equivalent blackbody image from the FPA-temperature-stabilized image to produce a difference image;
multiplying the difference image by a gain measured at the predetermined reference temperature of the FPA to produce a scaled difference image;
calculating a radiance corresponding to a blackbody at the measured shutter temperature; and
adding the calculated radiance to the scaled difference image to produce a radiometrically-calibrated measured radiance of the scene corresponding to the scene image.

8. The method of claim 7, wherein the measured FPA temperature is treated as being the measured temperature of the shutter.

9. A method for calibrating a thermal infrared (IR) imager, the method comprising:
determining a per-pixel ratio between a blackbody image and a shutter image as a function of shutter temperature, a shutter image being an image of a shutter of the thermal IR imager in a closed position;
acquiring a scene image;
acquiring a shutter image;
measuring the temperature of the shutter;
converting the shutter image to an equivalent blackbody image based on the determined per-pixel ratio at the measured shutter temperature; and
subtracting the equivalent blackbody image from the scene image to produce an offset-corrected scene image.

10. The method of claim 9, wherein the determining includes:
measuring the per-pixel ratio at a plurality of shutter temperatures using a controlled blackbody matched in temperature to the shutter temperature at each of the plurality of shutter temperatures; and
deriving a function from the measured per-pixel ratio at the plurality of shutter temperatures, the function permitting the per-pixel ratio for the measured shutter temperature to be calculated.

11. The method of claim 9, wherein a temperature measured at a focal plane array of the thermal IR imager is treated as being the measured shutter temperature.

12. The method of claim 9, further comprising:
multiplying the offset-corrected scene image by a gain of the thermal IR imager measured at a predetermined focal-plane-array temperature to produce a scaled offset-corrected scene image, the predetermined focal-plane-array temperature lying within a predetermined focal-plane-array temperature operating range of the thermal IR imager;
calculating a radiance corresponding to a blackbody at the measured shutter temperature; and
adding the calculated radiance to the scaled offset-corrected scene image to produce a radiometrically-calibrated measured radiance of the scene corresponding to the scene image.

13. The method of claim 9, wherein the thermal IR imager is a microbolometer camera lacking a thermoelectric cooler to stabilize the temperature of a focal plane array of the thermal IR imager.

14. The method of claim 9, wherein the thermal IR imager is a microbolometer camera that includes a thermoelectric cooler to stabilize the temperature a focal plane array of the thermal IR imager.

15. The method of claim 9, further comprising:
determining, prior to acquiring the scene image, correction coefficients in a model for an expected change in response of the thermal IR imager for a given temperature of a focal plane array (FPA) of the thermal IR imager with respect to a response of the thermal IR imager at a predetermined reference temperature of the FPA;
measuring the temperature of the FPA;
calculating a calibration gain for the measured FPA temperature based on at least one of the correction coefficients, the difference in temperature between the measured FPA temperature and the predetermined reference temperature of the FPA, and a calibration gain measured at the predetermined reference temperature of the FPA;
multiplying the offset-corrected scene image by the calculated calibration gain for the measured FPA temperature to produce a scaled offset-corrected scene image;
calculating a radiance corresponding to a blackbody at the measured shutter temperature; and
adding the calculated radiance to the scaled offset-corrected scene image to produce a radiometrically-calibrated measured radiance of the scene corresponding to the scene image.

16. The method of claim 15, wherein the measured shutter temperature is treated as being the measured temperature of the FPA.

17. A thermal infrared (IR) imaging system, comprising:
an image-formation subsystem including a lens and a focal plane array (FPA) configured to receive optical input via the lens; and
a stabilization and calibration computing subsystem comprising at least one processor and a memory containing a plurality of program instructions configured to cause the at least one processor to:
determine correction coefficients in a model for an expected change in response of the image-formation subsystem for a given temperature of the FPA with respect to a response of the image-formation subsystem at a predetermined reference temperature of the FPA;
acquire a scene image;
measure the temperature of the FPA; and
apply a correction to the scene image based on the correction coefficients and the difference between the measured FPA temperature and the predetermined reference temperature of the FPA to produce a FPA-temperature-stabilized image.

18. The thermal IR imaging system of claim 17, wherein the image-formation subsystem and the stabilization and calibration computing subsystem are integrated in a single thermal IR imaging device.

19. The thermal IR imaging system of claim 17, wherein the image-formation subsystem and the stabilization and calibration computing subsystem are implemented in separate devices that are capable of communicating with each other.

20. A thermal infrared (IR) imaging system, comprising:
an image-formation subsystem including a lens, a focal plane array (FPA) configured to receive optical input via the lens, and a shutter configured to control when the optical input is permitted to reach the FPA; and
a stabilization and calibration computing subsystem comprising at least one processor and a memory containing a plurality of program instructions configured to cause the at least one processor to:
determine a per-pixel ratio between a blackbody image and a shutter image as a function of shutter temperature, a shutter image being an image of the shutter in a closed position;
acquire a scene image;
acquire a shutter image;
measure the temperature of the shutter;
convert the shutter image to an equivalent blackbody image based on the determined per-pixel ratio at the measured shutter temperature; and
subtract the equivalent blackbody image from the scene image to produce an offset-corrected scene image.

21. The thermal IR imaging system of claim 20, wherein the image-formation subsystem and the stabilization and calibration computing subsystem are integrated in a single thermal IR imaging device.

22. The thermal IR imaging system of claim 20, wherein the image-formation subsystem and the stabilization and calibration computing subsystem are implemented in separate devices that are capable of communicating with each other.
